(19) United States
(12) Patent Application Publication
(10) Pub. No.: US 2013/0154533 A1
(43) Pub. Date: Jun. 20, 2013

(54) APPARATUS FOR EXTRACTING DRIVE CHARACTERISTIC OF DRIVE SYSTEM

(71) Applicants: Seok Won Lee, Whasung (KR); Woo Sung Yang, Whasung (KR)

(72) Inventors: Seok Won Lee, Whasung (KR); Woo Sung Yang, Whasung (KR)

(73) Assignee: Hyundai Motor Company, Seoul (KR)

(21) Appl. No.: 13/600,638

(22) Filed: Aug. 31, 2012

(30) Foreign Application Priority Data
Dec. 14, 2011 (KR) 10-2011-0134235

(51) Int. Cl. G01R 31/34

(52) U.S. Cl. 318/490

(57) ABSTRACT

Disclosed is an apparatus for extracting a drive characteristic of a drive system. The apparatus includes a drive unit supplying a rotating force to a drive shaft. A force-torque sensor unit is detachably coupled to the drive shaft of the drive unit, and may not rotate when it is coupled to the drive shaft. A load unit is detachably coupled to the drive shaft of the drive unit. A control unit is configured to control drive energy supplied to the drive unit, derive a drive-unit constant by using a relation between the input drive energy and measurement torque when the drive unit is coupled to the force-torque sensor unit, calculate frictional torque using the derived drive-unit constant, the input drive energy, an inertia moment and angular acceleration of the load unit when the drive unit is coupled to the load unit, and derive a frictional coefficient from the frictional torque.

### CROSS-REFERENCE TO RELATED APPLICATIONS

The present application claims priority to Korean Patent Application No. 10-2011-0134235 filed on Dec. 14, 2011, the entire contents of which is incorporated herein for purposes by this reference.

### BACKGROUND OF THE INVENTION

1. Field of the Invention

The present invention relates to an apparatus for extracting a dynamic characteristic parameter used in an experimental procedure in a mechanical system having an electric motor and a reduction gear so that the experiment is effective, etc. and an apparatus for extracting a drive characteristic of a drive system used in a method that uses experimental data to estimate a parameter.

2. Description of the Related Art

Drive sources for industrial equipment, vehicles and robots are gradually becoming more diversified. In particular, some manufactures have begun substituting or supplementing a conventional drive force obtained from an internal combustion engine or a hydraulic force with an electric drive source such as a motor. However, it is difficult to precisely calculate resistance loss and the frictional effect of various drive sources . Thus, it is difficult in practice to replace a system with another one or to develop a new system.

Particularly for robots, if the characteristic of the motor as a drive source installed at each joint is not accurately accounted for, no matter how excellent the control logic may be that is applied, many unpredictable variables occur during actual operation. Therefore, there is an urgent need for a technology capable of measuring and grasping the drive characteristic of a drive system in a simple and rapid manner before the device is actually operated. However, until now, there has been no method of accurately and rapidly measuring a drive characteristic including a motor constant, a coulomb frictional coefficient and a viscous frictional coefficient in the drive system, particularly in the drive system which includes the motor and the reduction gear.

The foregoing is designed merely to aid in the understanding of the background of the present invention, and is not intended to mean that the present invention falls within the purview of the related art that is already known to those skilled in the art.

### SUMMARY OF THE INVENTION

Accordingly, the present invention has been made keeping in mind the above problems occurring in the prior art, and an object of the present invention is to provide an apparatus for extracting a dynamic characteristic parameter to be used effectively in an experiment and an apparatus for extracting a drive characteristic of a drive system that deals with a parameter estimating method using experimental data, since a dynamic characteristic parameter such as a motor torque constant and a frictional coefficient caused by a joint frictional force must be clearly understood so that the driving of, e.g., a robot joint, may be optimized, as applied to a mechanical system including an electric motor and a reduction gear.

In order to accomplish the above object, the present invention provides an apparatus for extracting a drive characteristic of a drive system, including a drive unit configured to supply a rotating force to a drive shaft; a force-torque sensor unit detachably coupled to the drive shaft of the drive unit, the force-torque sensor unit not being rotatable when it is coupled to the drive shaft; a load unit detachably coupled to the drive shaft of the drive unit; and a control unit configured to control drive energy supplied to the drive unit, deriving a drive-unit constant by using a correlation between the input drive energy and measurement torque measured by a rotating force of the drive shaft from the force-torque sensor unit when the drive unit is coupled to the force-torque sensor unit, calculate a frictional torque using the derived drive-unit constant, the input drive energy, an inertia moment of the load unit, and angular acceleration of the load unit caused by a rotating force when the drive unit is coupled to the load unit, and deriving a frictional coefficient from the calculated frictional torque.

The drive unit may comprise a motor and a reduction gear. The drive energy may be applied as a current value that is applied to the motor, and the drive-unit constant may be applied as a constant value of the motor.

When deriving the drive-unit constant of the control unit, the force-torque sensor unit may be coupled to the drive shaft so that the force-torque sensor does not rotate. Further, when deriving the frictional coefficient of the control unit, the load unit may be coupled to the drive shaft in such a way as to rotate along with the drive shaft. The frictional coefficient may comprise a coulomb frictional coefficient and a viscous frictional coefficient. The control unit may derive the drive-unit constant by calculating a gradient by using least square fitting based on the input drive energy and data of the measurement torque.

In some exemplary embodiments, the drive unit may comprise a motor and a reduction gear, the drive energy may be applied as a current value that is applied to the motor, the drive-unit constant may be applied as a constant value of the motor, and the control unit may derive a motor constant by calculating a gradient by using least square fitting based on the input current value and data of the measurement torque.

The control unit may calculate the drive torque using the derived drive-unit constant and the input drive energy, and may calculate the frictional torque using the drive torque, the inertia moment of the load unit and the angular acceleration of the load unit caused by the rotating force.

In other exemplary embodiments, the drive unit may comprise a motor and a reduction gear, the drive energy may be applied as a current value that is applied to the motor, the drive-unit constant may be applied as a constant value of the motor, the frictional coefficient may comprise a coulomb frictional coefficient and a viscous frictional coefficient, and the control unit may derive the frictional coefficient by using a following equation.

τ_{f}=kₘi−I\dot{ω}

τ_{f}=α*sign(ω)+β*ω

(where τ_{f} is a frictional torque, kₘ is a motor constant of the drive unit, I is an inertia moment of the load unit, ω is an angular velocity of the load unit, α is a coulomb frictional coefficient, and β is a viscous frictional coefficient)

As apparent from the above description, advantages of an apparatus for extracting a drive characteristic of a drive system are that, in a mechanical system including an electric motor and a reduction gear, a motor torque constant for determining an output torque with respect to a current applied to the motor can be experimentally obtained, and the apparatus can easily cope with varying sizes due to various combinations of motors and gears, so that it is available as an adapter jig for optimizing parameters of a motor system, in addition to a robot component.

Further, the apparatus can extract a viscous frictional coefficient and a coulomb frictional coefficient caused by a joint frictional force, so that it may be utilized to optimize the driving of a joint as the frictional torque compensation of the joint.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a view showing a structure of an apparatus for extracting a drive characteristic of a drive system according to an exemplary embodiment of the present invention;

FIG. 2 is a graph showing a process of deriving a drive-unit constant of the apparatus for extracting the drive characteristic of the drive system according to an exemplary embodiment of the present invention; and

FIG. 3 is a graph showing a process of deriving a frictional coefficient of the apparatus for extracting the drive characteristic of the drive system according to an exemplary embodiment of the present invention.

### DESCRIPTION OF PREFERRED EMBODIMENTS

Hereinafter, an apparatus for extracting a drive characteristic of a drive system according to a preferred embodiment of the present invention will be described with reference to the accompanying drawings.

Furthermore, the control logic of the present invention may be embodied as non-transitory computer readable media on a computer readable medium containing executable program instructions executed by a processor, controller or the like. Examples of the computer readable mediums include, but are not limited to, ROM, RAM, compact disc (CD)-ROMs, magnetic tapes, floppy disks, flash drives, smart cards and optical data storage devices. The computer readable recording medium can also be distributed in network coupled computer systems so that the computer readable media is stored and executed in a distributed fashion, e.g., by a server or a network Additionally, although the exemplary embodiment is described as using one control unit to perform the above process, it is understood that the above processes may also be performed by a plurality of control units, controllers, processors or the like.

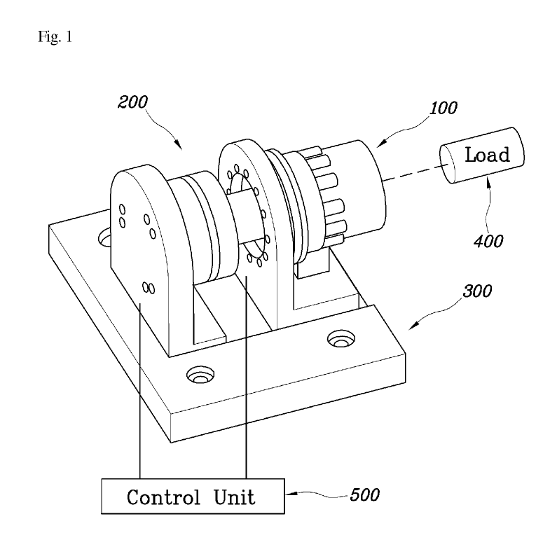

FIG. 1 is a view illustrating a structure of an apparatus for extracting a drive characteristic of a drive system according to an exemplary embodiment of the present invention. The apparatus for extracting the drive characteristic of the drive system according to the present invention includes a drive unit 100, a force-torque sensor unit 200, a load unit 400, and a control unit 500. The drive unit 100 supplies a rotating force to a drive shaft. The force-torque sensor unit 200 is detachably coupled to the drive shaft of the drive unit 100, and is not rotatable when it is coupled to the drive shaft. The load unit 400 is detachably coupled to the drive shaft of the drive unit 100. The control unit 500 controls drive energy supplied to the drive unit 100, derives a drive-unit constant through a relation between the input drive energy and measurement torque measured by a rotating force of the drive shaft from the force-torque sensor unit 200 when the drive unit 100 is coupled to the force-torque sensor unit 200. The control unit then calculates frictional torque using the derived drive-unit constant, the input drive energy, an inertia moment of the load unit, and the angular acceleration of the load unit caused by a rotating force when the drive unit is coupled to the load unit, and derives a frictional coefficient from the calculated frictional torque.

According to the present invention, first, the force-torque sensor unit 200 is secured to a base in such a way that the force-torque sensor unit 200 is not able to rotate. Then, drive energy is applied from the control unit 500, and the relation between the drive energy and data measured from the sensor unit 200 is calculated, thus deriving the drive-unit constant. Subsequently, the force-torque sensor unit is detached, and instead, the load unit 400 is connected to the drive shaft. Here, the load unit is rotatably connected to the drive shaft. Further, the control unit applies drive energy again, and calculates the correlation between the drive energy and measured data, thus deriving a frictional coefficient. Thus, the drive efficiency of the drive unit itself, namely, the drive-unit constant, and the frictional coefficient are finally obtained using such an apparatus. Further, these results can be used for various mechanical designs, and particularly for the optimization of joint driving, such as the frictional torque compensation of a joint of a robot or the like.

Also, the drive unit 100 may include a motor and a reduction gear, the drive energy may be applied as a current value that is applied to the motor, and the drive-unit constant may be applied as a constant value of the motor. That is, the drive unit may include the motor and the reduction gear (may also include an encoder to measure an angular velocity), and the drive energy applied to the drive unit 100 may apply the current value as a representative value. It is possible to use several different drive systems in the illustrative embodiment of the present invention as well. The following embodiment will be described with reference to the motor and the reduction gear.

To be more specific, when deriving the drive-unit constant of the control unit 500, the force-torque sensor unit 200 is coupled to the drive shaft so that it is not able to rotate. Further, the control unit calculates a gradient through a least square fitting based on the input drive energy and the data of the measurement torque, thus deriving the drive-unit constant. That is, the drive unit 100 may include a motor and a reduction gear, and the drive energy may be applied as a current value that is applied to the motor, and the drive-unit constant may be applied as a constant value for the motor. The control unit derives a motor constant by calculating a gradient using least square fitting based on the input current value and data of the measurement torque.

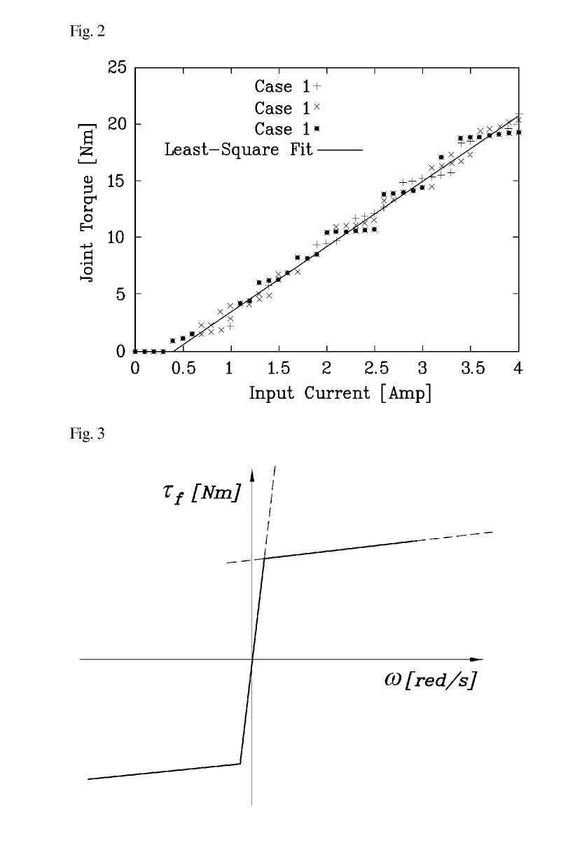

To be more specific, FIG. 2 is a graph illustrating a process of deriving a drive-unit constant of the apparatus for extracting the drive characteristic of the drive system according to an embodiment of the present invention. Referring to the graph, an X-axis denotes an applied current value, and a Y-axis denotes measurement torque measured from the force-torque sensor unit. Further, discrete data is obtained using the current value and the measurement torque. If a relation between the current value and the measurement torque is linearly represented using the least square fitting, the motor constant, that is, a torque constant representing the efficiency of the motor, can be obtained.

Meanwhile, when deriving the frictional coefficient of the control unit, the load unit may be coupled to the drive shaft in such a way as to rotate along with the drive shaft. The frictional coefficient may include a coulomb frictional coefficient and a viscous frictional coefficient. Thus, the control unit may be configured to calculate the drive torque using the derived drive-unit constant and the input drive energy, and calculate the frictional torque using the drive torque, the inertia moment of the load unit and the angular acceleration of the load unit by the rotating force.

To be more specific, FIG. 3 is a graph illustrating a process of deriving a frictional coefficient of the apparatus for extracting the drive characteristics of the drive system according to an exemplary embodiment of the present invention. As stated above, the drive unit 100 may include a motor and a reduction gear, the drive energy may be applied as a current value that is applied to the motor, and the drive-unit constant may be applied as a constant value of the motor. The frictional coefficient may include a coulomb frictional coefficient and a viscous frictional coefficient. The control unit derives the frictional coefficient using the following equation.

τ_{f}=kₘi−I\dot{ω}

τ_{f}=α*sign(ω)+β*ω

(where τ_{f} is a frictional torque, kₘ is a motor constant of the drive unit, I is an inertia moment of the load unit, ω is an angular velocity of the load unit, α is a coulomb frictional coefficient, and β is a viscous frictional coefficient)

As such, the motor constant of the motor is first calculated using the force-torque sensor unit 200. Further, ideally, as in I\dot{ω}=τ_{α} (τₐ is drive torque of the motor), the drive torque of the motor may be entirely transmitted to the load unit. However, a frictional force is present in the motor by the coupling of the load unit. Further, in light of the frictional force, the equation of I\dot{ω}=τ_{α}−τ_{f} is established. As mentioned above, when considering a current transmitted to the drive unit under the control of the control unit and a motor constant of the motor itself, the equations of τ_{α}kₘi and τ_{f}=kₘi−I\dot{ω} are established.

Once the frictional torque is calculated as the function of the angular velocity using the above relation, the graph of FIG. 3 can be obtained. In this graph, a very sharp portion of the gradient shows a portion where the coulomb friction is strongly affected, and a gentle portion of the gradient shows a portion where viscous friction is strongly affected. Thus, when the measured result is represented linearly, it is expressed as shown in FIG. 3. When applying the result to the equation of τ_{f}=α*sign(ω)+β*ω, α can be obtained as the coulomb frictional coefficient, and β can be obtained as the viscous frictional coefficient.

As described above, the present invention provides an apparatus for extracting a drive characteristic of a drive system, in which, in a mechanical system including an electric motor and a reduction gear, a motor torque constant for determining an output torque with respect to a current applied to the motor can be experimentally obtained, and the apparatus can easily cope with differing sizes due to various combinations of motors and gears, so that it is available as an adapter jig for optimizing parameters of a motor system, in addition to a robot component. Further, the apparatus can extract a viscous frictional coefficient and a coulomb frictional coefficient caused by a joint frictional force, so that it can be utilized to optimize the driving of a joint such as the frictional torque compensation of the joint.

Although the preferred embodiment of the present invention has been disclosed for illustrative purposes, those skilled in the art will appreciate that various modifications, additions and substitutions are possible, without departing from the scope and spirit of the invention as disclosed in the accompanying claims

What is claimed is:

1. An apparatus for extracting a drive characteristic of a drive system, comprising:
a drive unit configured to supply a rotating force to a drive shaft;
a force-torque sensor unit detachably coupled to the drive shaft of the drive unit;
a load unit detachably coupled to the drive shaft of the drive unit; and
a control unit configured to control drive energy supplied to the drive unit, derive a drive-unit constant by using a relation between the input drive energy and measurement torque measured by a rotating force of the drive shaft from the force-torque sensor unit when the drive unit is coupled to the force-torque sensor unit, calculate a frictional torque using the derived drive-unit constant, the input drive energy, an inertia moment of the load unit, and angular acceleration of the load unit caused by a rotating force when the drive unit is coupled to the load unit, and deriving a frictional coefficient from the calculated frictional torque.

2. The apparatus as set forth in claim 1, wherein the drive unit comprises a motor and a reduction gear, the drive energy is applied as a current value that is applied to the motor, and the drive-unit constant is applied as a constant value of the motor.

3. The apparatus as set forth in claim 1, wherein, when deriving the drive-unit constant of the control unit, the force-torque sensor unit is coupled to the drive shaft in such a way as not to rotate, and, when deriving the frictional coefficient of the control unit, the load unit is coupled to the drive shaft in such a way as to rotate along with the drive shaft

4. The apparatus as set forth in claim 1, wherein the frictional coefficient comprises a coulomb frictional coefficient and a viscous frictional coefficient.

5. The apparatus as set forth in claim 1, wherein the control unit derives the drive-unit constant by calculating a gradient by using least square fitting based on the input drive energy and data of measured torque.

6. The apparatus as set forth in claim 1, wherein the drive unit comprises a motor and a reduction gear, the drive energy is applied as a current value that is applied to the motor, the drive-unit constant is applied as a constant value of the motor, and the control unit is configured to derive a motor constant by calculating a gradient by using least square fitting based on the input current value and data related to the measured torque.

7. The apparatus as set forth in claim 1, wherein the control unit is configured calculate the drive torque using the derived drive-unit constant and the input drive energy, and calculate the frictional torque using the drive torque, the inertia moment of the load unit and the angular acceleration of the load unit caused by the rotating force.

8. The apparatus as set forth in claim 1, wherein the drive unit comprises a motor and a reduction gear, the drive energy is applied as a current value that is applied to the motor, the drive-unit constant is applied as a constant value of the motor, the frictional coefficient comprises a coulomb frictional coefficient and a viscous frictional coefficient, and the control unit is configured to derive the frictional coefficient by using a following equation,
τ_{f}=kₘi−I\dot{ω}
τ_{f}=α*sign(ω)+β*ω
where τ_{f} is a frictional torque, kₘ is a motor constant of the drive unit, I is an inertia moment of the load unit, ω is an angular velocity of the load unit, α is a coulomb frictional coefficient, and β is a viscous frictional coefficient.
